(19) United States
(12) Patent Application Publication
(10) Pub. No.: US 2026/0300206 A1
(43) Pub. Date: Oct. 1, 2026

(54) TRANSMIT DRIVER IMPEDANCE CALIBRATION TECHNIQUES FOR BIDIRECTIONAL SERIALIZER/DESERIALIZER

(71) Applicant: Marvell Asia Pte Ltd, Singapore (SG)

(72) Inventors: Wenjie Zheng, Singapore (SG); Jianmin Guo, Fremont, CA (US); Xin Ma, San Jose, CA (US); Hui Wang, Pleasanton, CA (US)

(73) Assignee: Marvell Asia Pte Ltd, Singapore (SG)

(21) Appl. No.: 19/577,685

(22) Filed: Mar. 25, 2026

Related U.S. Application Data
(60) Provisional application No. 63/779,261, filed on Mar. 27, 2025.

(51) Int. Cl. G06F 13/40; G06F 13/42; H03M 1/10

(52) U.S. Cl. CPC G06F 13/4086; G06F 13/4072; H03M 1/1009; G06F 13/4282

(57) ABSTRACT

A method for calibrating impedance of a first transmit (TX) driver of a first bidirectional serializer/deserializer (SerDes), wherein the first bidirectional SerDes is connected to a second bidirectional SerDes by a data transmission line and the second bidirectional SerDes comprises a second TX driver, wherein the method includes, for each of a plurality of driver impedance code values applied to the first TX driver, receiving at the second SerDes a transmission of a data pattern corresponding to the impedance code value; and measuring at the second SerDes an eye height of a data sequence transmitted by the second SerDes. The method further includes determining which of the measured eye heights comprises a maximum eye height and communicating to the first SerDes from the second SerDes the impedance code value corresponding to the one of the eye heights comprising the maximum eye height for the first TX driver.

### PRIORITY APPLICATION

This patent application claims priority to and/or the benefit of U.S. Provisional Application No. 63/779,261 entitled, “New Transmit (Tx) Driver Impedance Calibration Method for Bidirectional SerDes,” filed on Mar. 27, 2025, which is hereby incorporated by reference in its entirety.

### BACKGROUND

The impedance of a bidirectional serializer/deserializer (SerDes) transmit (TX) driver may be calibrated such that the output impedance of the driver is the same as the characteristic impedance of a transmission line to which the SerDes is connected. The purpose of TX driver impedance calibration is to minimize reflection of the output signal of the TX driver, thereby maximizing the signal eye height that may be achieved on the transmission line.

Impedance calibration in connection with a bidirectional serializer/deserializer (SerDes) transmit (TX) driver has typically been accomplished using a scaled replica driver, constant current, and constant bandgap voltage to achieve target impedance for the primary driver. This technique suffers from several deficiencies, including but not limited to low accuracy. Additionally, the fact that it must be integrated into each TX lane in a SerDes means that it increases the footprint of the circuitry, as well as unnecessarily increasing power consumption. Accordingly, a more efficient technique for performing TX driver impedance calibration is needed.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A illustrates a block diagram of processor module including an AI server processor, according to some embodiments of the disclosure.

FIG. 1B illustrates a block diagram of die-to-die clocking and serializer-deserializer (SerDes) circuitry of the processor module of FIG. 1A, according to some embodiments of the disclosure.

FIG. 2 illustrates an example eye diagram, according to some embodiments of the disclosure.

FIGS. 3A-3B illustrate a block diagram of an example system for performing TX driver impedance calibration in a bidirectional SerDes, according to some embodiments of the disclosure.

FIG. 4 illustrates a flowchart of example operations performed in connection with the system for performing TX driver impedance calibration in a bidirectional SerDes of FIGS. 3A-3B, according to some embodiments of the disclosure.

### DETAILED DESCRIPTION

### Overview

In accordance with features of embodiments described herein, innovative techniques for performing TX driver impedance calibration in a bidirectional SerDes system are described. In particular embodiments, the TX drivers on both ends of a set of transmission lines transfer data simultaneously, with each driver being treated as the resistor termination for the opposite driver. The eye height of each TX driver will be maximized when the impedance of the opposite TX driver is equal to the characteristic impedance of the transmission lines. In accordance with features of embodiments described herein, the TX driver impedance calibration techniques directly monitor the eye height of the TX driver and adjusts the impedance of the opposite TX driver using sideband communications accordingly, thereby eliminating the need for a replica driver, constant current, and bandgap voltage necessitated by previous calibration techniques.

### Exemplary AI Server Processor

An AI server processor is a high-performance integrated circuit designed to execute compute-intensive workloads, such as AI inference, training, and large-scale server operations. Such AI server processors typically include several common components, including a scalable core complex, a die-to-die interconnect (I/O subsystem), phase-locked loops (PLLs), memory hierarchy, and power and thermal management.

A scalable core complex may include a plurality of processing cores arranged in a scalable architecture to support varying performance and power requirements. Each core may include vector or matrix acceleration units optimized for AI workloads, along with general-purpose execution pipelines for server tasks. The cores may be interconnected through a high-bandwidth on-die fabric, enabling low-latency communication and dynamic workload distribution.

A die-to-die interconnect, or I/O subsystem, may include high-speed die-to-die interfaces for connecting multiple processor dies within a package or across chiplets, which interfaces may utilize advanced signaling techniques to achieve low-latency and high-throughput for memory access and inter-processor communication. The I/O subsystem often supports coherent protocols to maintain data consistency across dies.

PLL circuits may be employed to generate and synchronize clock signals for the processor cores and I/O interfaces. Multiple PLLs may be distributed across the die to provide localized clock domains, ensuring timing integrity for high-speed links and scalable core clusters. PLLs may also enable dynamic frequency scaling to optimize performance and power efficiency.

Memory hierarchy may include integrated cache structures (e.g., L1, L2, and shared L3) for reducing memory access latency. External memory controllers may be provided for supporting double data rate (DDR), HBM, or other high-bandwidth memory technologies for large-scale data processing.

Power and thermal management may include on-die power delivery networks and voltage regulators for fine-grained control of core and I/O power states. Thermal sensors and dynamic throttling mechanisms may be provided to maintain operational reliability under heavy workloads.

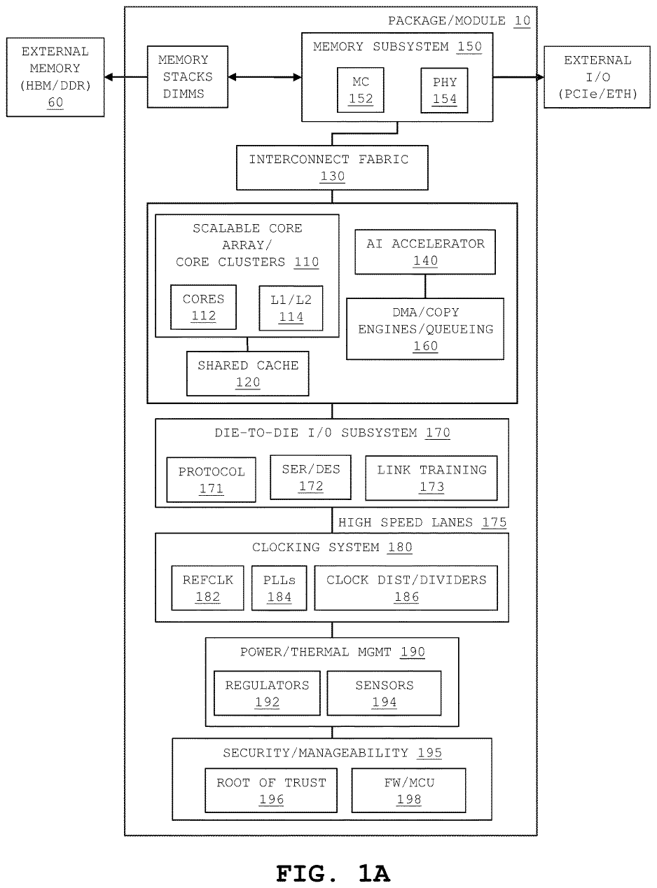

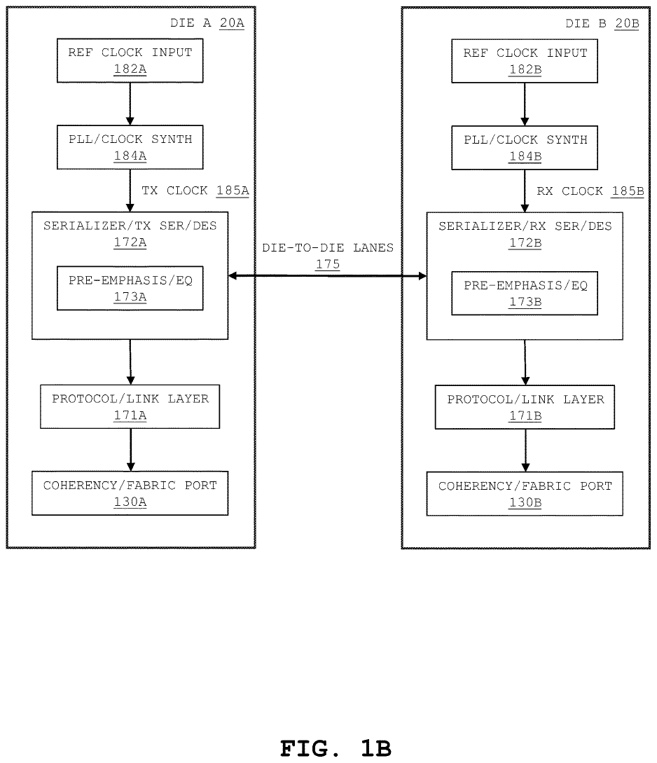

FIG. 1A illustrates a processor module 10 including an AI server processor 100 configured for scalable compute throughput and multi-die expansion. Processor 100 includes scalable core array 110 coupled to interconnect fabric 130. Scalable core array 110 includes a plurality of processor cores 112 arranged as one or more core clusters, core tiles, or core complexes, with private or semi-private cache resources such as L1/L2 cache 114. Interconnect fabric 130 provides communication among scalable core array 110, shared cache 120, AI accelerator 140, memory subsystem 150, and die-to-die I/O subsystem 170. Shared cache 120 provides a shared last-level cache (LLC), system-level cache (SLC), or another shared caching structure supporting reduced off-die bandwidth demand and reduced average memory access latency for workloads including AI inference, AI training, and server processing.

AI accelerator 140 includes one or more fixed-function or programmable engines that execute matrix, vector, or tensor operations, with data paths supporting parallel multiply-accumulate (MAC) operations and optional sparsity, quantization, or mixed-precision processing. DMA/copy engines 160 support movement of data among shared cache 120, memory subsystem 150, AI accelerator 140, and peripheral interfaces, with queueing structures and command processors supporting asynchronous transfers, scatter-gather operations, and memory-to-memory copy operations.

Memory subsystem 150 includes one or more memory controllers 152 and one or more memory physical interfaces (PHYs) 154 that couple processor 100 to external memory 60. External memory 60 includes high-bandwidth memory (HBM), double data rate memory (DDR), or another memory technology. Memory controller 152 supports scheduling, refresh, ordering rules, and quality-of-service (QoS) arbitration, while memory PHY 154 supports high-speed signaling, training, and calibration for memory channels.

Die-to-die I/O subsystem 170 provides high-speed communication between processor 100 and at least one additional die or chiplet within module 10. Die-to-die I/O subsystem 170 includes protocol layer 171, serializer/deserializer circuitry (SerDes) 172, and link training/equalization circuitry 173. Protocol layer 171 supports packetization, ordering, flow control, and optional coherency semantics for transactions that traverse die-to-die lanes 175. Link training/equalization circuitry 173 supports lane initialization, deskew, equalization setting selection, margining, and retry behavior. Die-to-die lanes 175 support high-throughput point-to-point signaling implemented as parallel single-ended lanes, differential lanes, or a combination thereof, with optional forward error correction (FEC) and cyclic redundancy check (CRC) protection. In some embodiments, die-to-die I/O subsystem 170 supports coherent communication that maintains cache coherence across shared cache 120 instances distributed across multiple dies, with protocol layer 171 exchanging coherence messages and associated data payloads over die-to-die lanes 175.

Clocking system 180 supports timing generation and distribution for scalable core array 110, interconnect fabric 130, memory subsystem 150, and die-to-die I/O subsystem 170. Clocking system 180 includes reference clock source 182, one or more PLLs 184, and clock distribution/divider circuitry 186. Reference clock source 182 provides a reference frequency derived from an oscillator, board clock, or package-distributed clock. PLL 184 generates one or more synthesized clocks having frequencies and phases suitable for core clock domains, fabric clock domains, memory clock domains, and I/O clock domains. PLL 184 provides frequency multiplication and optional fractional synthesis, jitter filtering, and phase alignment to support timing closure for high-speed interfaces. Clock distribution/divider circuitry 186 distributes synthesized clocks to clock domains and may include dividers, multiplexers, glitchless clock switching logic, clock gating cells, and clock-domain-crossing (CDC) support circuitry. In some embodiments, clocking system 180 includes separate PLL instances 184 assigned to distinct domains, including a core PLL instance supporting scalable core array 110 and an I/O PLL instance supporting die-to-die I/O subsystem 170, with independent voltage and frequency scaling per domain.

Power and thermal management subsystem 190 supports power delivery and reliability for processor 100. Subsystem 190 includes voltage regulation circuitry 192 and sensor circuitry 194. Voltage regulation circuitry 192 includes integrated voltage regulators, low-dropout regulators, switched-capacitor regulators, or digitally controlled external regulator interfaces. Sensor circuitry 194 includes temperature sensors, voltage monitors, current monitors, and performance counters used to enforce power limits and thermal limits. In some embodiments, subsystem 190 controls dynamic voltage and frequency scaling (DVFS) via control of PLL 184 and domain voltage rails, with policies that maintain performance targets while satisfying thermal and power constraints.

Security/manageability subsystem 195 supports platform security and operational management. Subsystem 195 includes root-of-trust circuitry 196 and management controller or firmware processor 198. Root-of-trust circuitry 196 supports secure boot, key storage, attestation, and cryptographic primitives. Management controller 198 supports telemetry, debug access controls, and lifecycle management functions including configuration of die-to-die I/O subsystem 170, configuration of clocking system 180, and configuration of power/thermal management subsystem 190.

FIG. 1B illustrates a die-to-die lane clocking arrangement implemented by die 20A coupled to die 20B through die-to-die lanes 175. Die 20A includes reference clock input 182A coupled to PLL 184A. PLL 184A generates transmit (TX) clock 185A that drives serializer/TX SerDes 172A. Serializer/TX SerDes 172A transmits serialized data over die-to-die lanes 175 with link conditioning via equalization circuitry 173A. Die 20B includes reference clock input 182B coupled to PLL 184B. In an embodiment, PLL 184B generates one or more receive (RX) clocks 185B that support sampling and recovery for deserializer/RX SerDes 172B. In another embodiment, deserializer/RX SerDes 172B includes clock-data recovery (CDR) within circuitry 173B that recovers sampling phase from transitions embedded in lane signaling, with PLL 184B providing a low-jitter local reference used for CDR loop stability or retiming. Protocol/link layer 171A and protocol/link layer 171B perform link initialization, lane alignment, deskew, and integrity checks, then present transactions to coherency/fabric ports 130A and 130B. Arrangement supports scalable multi-die construction by replicating die-to-die instances and scaling lane counts, with PLL instances supporting clock-domain isolation and jitter management for increasing link speeds.

### Example Eye Height in Data Transmission Systems

The quality, or integrity, of a digital signal as it travels from a transmitter to a receiver via a transmission channel can be affected by many factors, including the transmitter itself, the transmission channel, and connectors, for example, cables or PCB traces, and connectors. The signal quality is also referred to as signal integrity. An eye diagram is a graphical tool that may be used to evaluate the quality of a digital signal and may be described as an infinite persisted overlay of all bits captured by an oscilloscope to show when bits are valid, providing a composite picture of the overall quality of the characteristics of the physical layer of a system. An eye diagram covers all possible combinations of variations affecting the signal, including amplitude, timing uncertainties, and infrequent signal anomalies.

Eye height is to the peak-to-peak vertical measurement of an eye diagram (typically measured at the center of the eye) and corresponds to the signal-to-noise ratio (SNR) of the transmitted signal represented by the eye diagram. As such, eye height indicates the amount of noise present in a transmitted signal. A larger eye height/more open eye indicates less noise in the transmitted signal, while a smaller eye height/more closed eye indicates significant signal degradation. Eye height is used to determine signal quality in systems and as such is a key metric in evaluating digital communication signals.

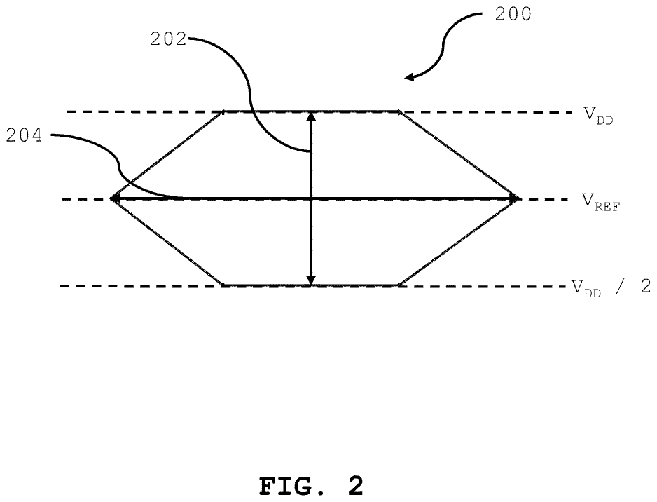

FIG. 2 illustrates a diagram of an eye 200 having an eye height 202 measured at horizontal center of eye 200. As shown in FIG. 2, eye height 202 extends between low voltage V_{L} and a high voltage V_{H}. An eye width 204 of eye 200 is measured at a vertical center of eye 200, which in the illustrated diagram corresponds to a reference voltage V_{REF}.

### Exemplary System for TX Driver Impedance Calibration in Bidirectional SerDes System

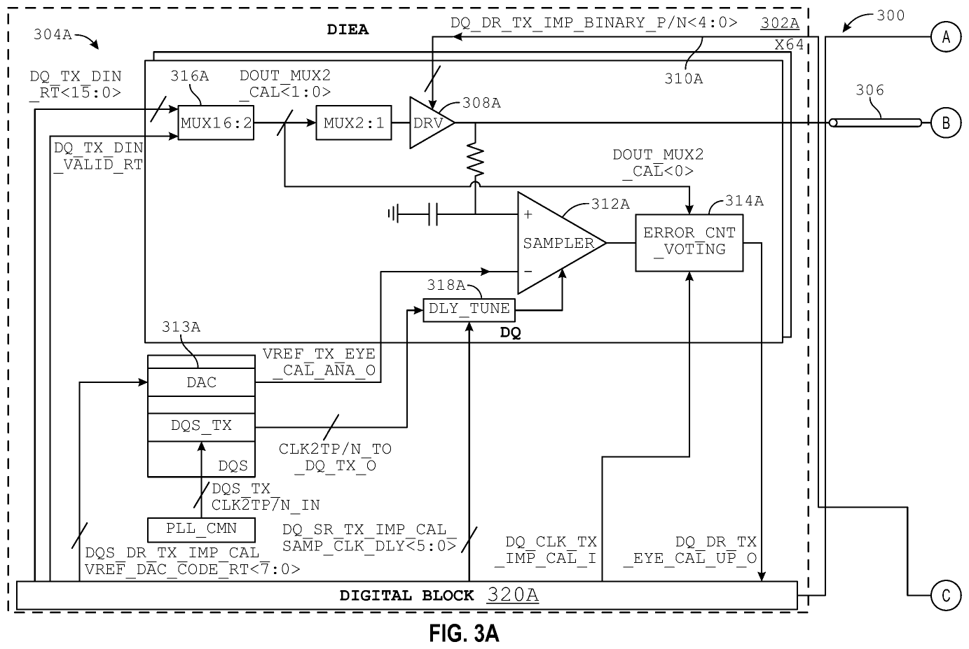

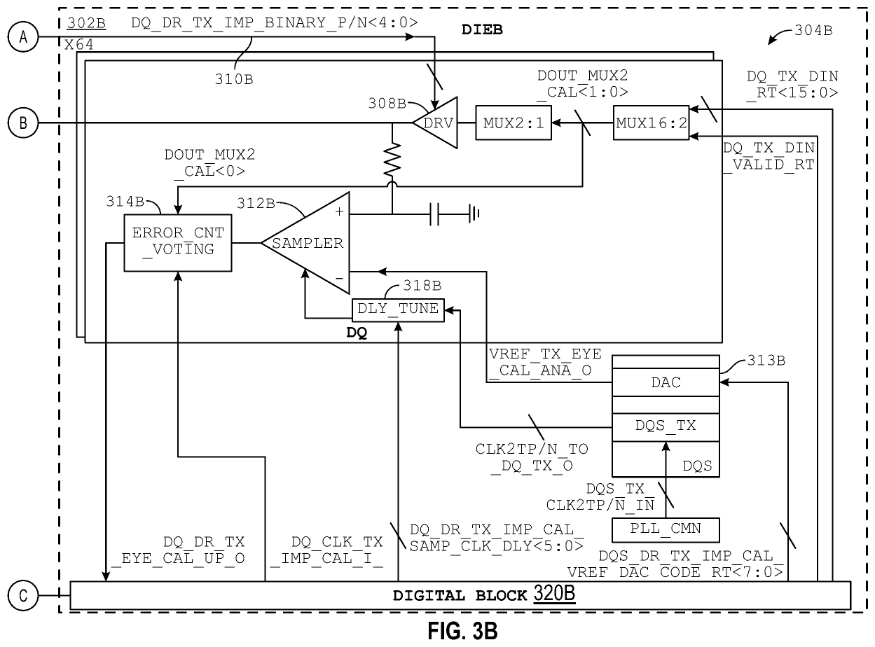

FIGS. 3A-3B illustrate a block diagram of an example 300 system for performing TX driver impedance calibration in a bidirectional SerDes, according to some embodiments of the disclosure. As shown in FIGS. 3A-3B, system 300 includes first and second dies 302A, 302B, each including TX circuitry 304A, 304B, connected via a bidirectional die-to-die lanes 306. In particular embodiments, there are 64 die-to-die lanes, each with corresponding TX circuitry; however, for purposes of simplicity and ease of explanation and illustration, only a single representative lane (with corresponding TX circuitry) is shown in and described with reference to FIGS. 3A-3B.

Each TX circuitry 304A, 304B, includes a TX driver 308A, 308B, the impedance of which, as previously noted, must be calibrated prior to (and possibly periodically and/or continuously throughout) use thereof. Sidebands 310A, 310B, are provided for use during the calibration process, as will be described in greater detail hereinbelow.

Each TX circuitry 304A, 304B, further includes a sampler 312A, 312B, which samples data output from driver 308A, 308B, as controlled by an impedance code setting of a digital-to-analog converter (DAC) 313A, 313B. Output of each sampler 312A, 312B, is input to an error count module 314A, 314B, the other input of which is connected to receive local data output a 16:2 MUX 316A, 316B. In particular embodiments may be implemented as a comparator for comparing the input data streams and outputting a flag (e.g., DQ_DR_TX_EYE_CAL_UP_O) bit indicative of whether the input data matches (e.g., a 0) or does not match (e.g., a 1). A delay tune module 318A, 318B, controls clock delay tuning of sampler 312A, 312B. Digital block 320A, 320B, provides processing and memory functionality for TX circuitry 304A, 304B.

Continuing to refer to FIGS. 3A-3B, select signals illustrated therein are defined in TABLE 1 below.

TABLE I

| | Signal | |
|---|---|---|
| Signal Name | Type | Description |
| DQS_DR_IMP_CAL_VREF_DAC_CODE_RT[7:0] | I | TX self-eye measurement VREF code |
| | | 0x0: VREF = 0 |
| | | 0x1: VREF = VDD/255 |
| | | 0x2: VREF = VDD*2/255 |
| | | . . . |
| DQ_SR_TX_IMP_CAL_SAMP_CLK_DLY[5:0] | I | TX eye calibration sampler clock |
| | | delay tuning. |
| | | 0x0: 1 ps |
| | | . . . |
| | | 0x3F: 31 ps |
| DQ_CLK_TX_IMP_CAL_I | I | Calibration period clock for TX eye |
| | | calibration |
| DQ_DR_TX_EYE_CAL_UP_O | O | TX eye calibration error count |
| | | voting result. |
| | | 0x0: no error. |
| | | 0x1: with error. |
| DQ_TX_DIN_RT[15:0] | I | Input data for serializer. |
| DQ_TX_DIN_VALID_RT | I | Data valid signal |
| DQ_DR_TX_IMP_BINARY_N[4:0] | I | TX driver pulldown res tuning. |

### Exemplary Operations for TX Driver Impedance Calibration in Bidirectional SerDes System

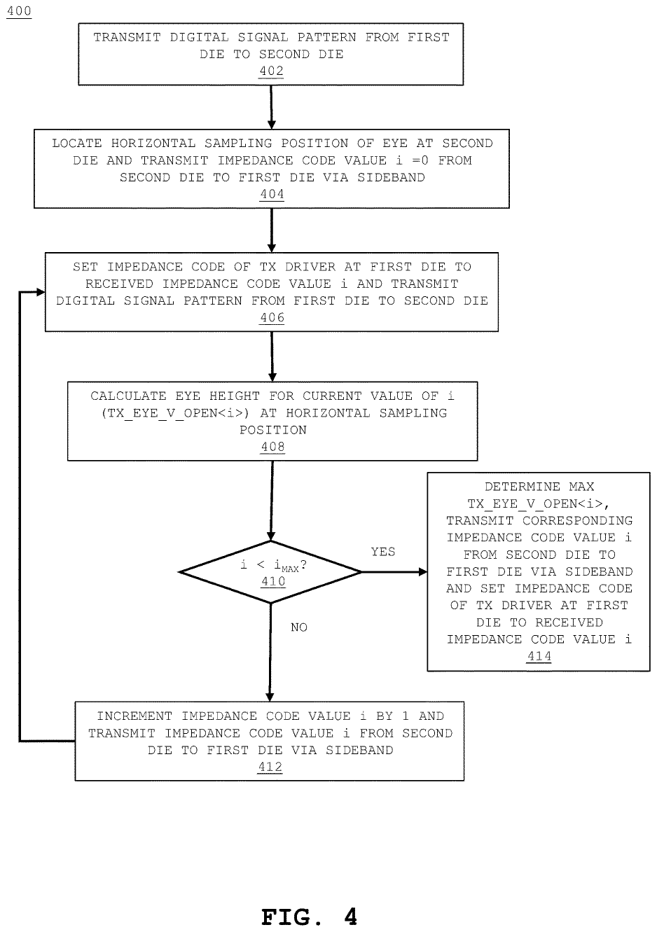

FIG. 4 illustrates a flowchart 400 of example operations performed in connection with a system for performing TX driver impedance calibration in a bidirectional SerDes, such as system 300 (FIGS. 3A-3B), according to some embodiments of the disclosure. In certain embodiments, one or more of the operations illustrated in FIG. 4 may be performed by one or more of the elements illustrated in FIGS. 1A, 1B, and 3, for example.

In an operation 402, a preselected digital signal pattern is transmitted from the first die (e.g., die 302A (FIGS. 3A-3B)) to the second die (e.g., die 302B (FIGS. 3A-3B)). In a particular embodiment, the presented digital signal pattern comprises a series of 1s, although it is anticipated that other patterns may be used. In particular embodiments, the operation 402 may be accomplished by setting DQ_DR_TX_IMP_BINARY_P/N<4:0> to MAX/2, setting DQ_TX_DIN_RT to 1111 . . . 111 and setting DQ_TX_DIN_VALID_RT to 1.

In an operation 404, at the second die (e.g., die 302B (FIGS. 3A-3B)), the horizontal sampling position of the eye is determined. In particular embodiments, the operation 404 may be accomplished by transmitting a pseudorandom binary sequence (PRBS), e.g., PRBS7, to the first die (e.g., die 302A (FIGS. 3A-3B)), sweeping DQ_SR_TX_IMP_CAL_SAMP_CLK_DLY<5:0> across all values while monitoring DQ_DR_TX_EYE_CAL_UP_O, identifying the minimum (min_DLY) and maximum (max_DLY) DQ_SR_TX_IMP_CAL_SAMP_CLK_DLY<5:0> code for DQ_DR_TX_EYE_CAL_UP_O=0, and setting DQ_SR_TX_IMP_CAL_SAMP_CLK_DLY<5:0> to (min_DLY+max_DLY)/2. Once the horizontal sampling position of the eye is determined, an impedance code value (i) is set to 0 and sent to the first die (e.g., die 302A (FIGS. 3A-3B)) via sideband (e.g., sideband 310A (FIGS. 3A-3B)).

In an operation 406, at the first die (e.g., die 302A (FIGS. 3A-3B)) the impedance code of the transmission driver (e.g., TX driver 308A (FIGS. 3A-3B)) is set to the impedance value i transmitted via sideband in the operation 404 and the preselected digital pattern is once again transmitted to the second die (e.g., die 302B, (FIGS. 3A-3B)). In particular embodiments, this operation may be accomplished by setting DQ_DR_TX_IMP_BINARY_P/N<4:0> to MAX/2, setting DQ_TX_DIN_RT to 1111 . . . 111 and setting DQ_TX_DIN_VALID_RT to 1, as in the operation 402 above.

In an operation 408, at the second die (e.g., die 302B (FIGS. 3A-3B)), the eye height for the current value of i at the horizontal sampling position determined in operation 404 is calculated. In particular embodiments, this operation may be accomplished by transmitting a PRBS, e.g., PRBS7, to the first die (e.g., die 302A (FIGS. 3A-3B)), sweeping DQS_DR_TX_IMP_CAL_VREF_DAC_CODE_RT<7:0> across all values while monitoring DQ_DR_TX_EYE_CAL_UP_O, identifying the minimum (min_CAL) and maximum (max_CAL) DQS_DR_TX_IMP_CAL_VREF_DAC_CODE_RT<7:0> code for DQ_DR_TX_EYE_CAL_UP_O=0, and setting TX_EYE_V_OPEN<i> to max_CAL-min_CAL.

In an operation 410, at the second die (e.g., die 302B (FIGS. 3A-3B)), a determination is made whether the current value of i is equal to iₘₐₓ. In particular embodiments, iₘₐₓ may be equal to 15. If a negative determination is made in operation 410, execution proceeds to an operation 412; otherwise, execution proceeds to an operation 414.

In the operation 412, at the second die (e.g., die 302B (FIGS. 3A-3B)), the impedance code value i is incremented by 1 and the current (i.e., incremented) value of i is transmitted to the first die (e.g., die 302A (FIGS. 3A-3B)) via sideband (e.g., sideband 310A (FIGS. 3A-3B)). Execution then returns to the operation 406 and continues in this manner until a positive determination is made in the operation 410, at which point execution proceeds to the operation 414.

In the operation 414, at the second die (e.g., die 302B (FIGS. 3A-3B)), the maximum one of the eye heights calculated in the operation 408 is determined and the impedance code value i corresponding to the determined maximum one of the calculated eye heights is transmitted to the first die (e.g., die 302A (FIGS. 3A-3B)).

In an operation 416, at the first die (e.g., die 302A (FIGS. 3A-3B)) the impedance code of the TX driver (e.g., TX driver 308A (FIGS. 3A-3B)) is set to the value i transmitted via sideband in the operation 414, at which point, the TX driver is calibrated.

Although the operations shown in and described with reference to FIG. 4 are illustrated as occurring once each and in a particular order, it will be recognized that the operations may be performed in any suitable order and repeated as desired. Additionally, one or more operations may be performed in parallel. Furthermore, the operations illustrated in FIG. 4 may be combined or may include more or fewer details than described.

It should further be noted that the operations shown in FIG. 4 may be performed for each lane, in which case operations may be performed for all lanes simultaneously or substantially simultaneously (e.g., completing each operation for every lane before proceeding to the next operation) or may be performed for all lanes sequentially (e.g., with all operations performed for one lane before operations are performed for the next lane), for example. It should also be noted that the method 400 may be performed periodically or may be performed substantially continuously in the background. Finally, it should be noted that the method 400 should be performed for each die (e.g., substituting first die for second die and second die for first die in the operations described above).

### Select Examples

1. A method for calibrating an impedance of a first transmit (TX) driver of a first bidirectional serializer/deserializer (SerDes), wherein the first bidirectional SerDes is connected to a second bidirectional SerDes by a data transmission line, the second bidirectional SerDes comprising a second TX driver, the method comprising: for each of a plurality of driver impedance code values applied to the first TX driver measuring at the second SerDes an eye height of an eye of a data sequence transmitted by the second SerDes; determining which of the measured eye heights comprises a maximum eye height; and communicating to the first SerDes from the second SerDes the driver impedance code value corresponding to the one of the eye heights comprising the maximum eye height for the first TX driver.

2. The method of claim 1, further comprising identifying at the second SerDes a horizontal sampling position of the eye, wherein for each of the plurality of driver impedance code values, the measuring at the second SerDes the eye height is performed at the horizontal sampling position.

3. The method of claim 1 or 2, further comprising: for each of a plurality of second driver impedance code values applied to the second TX driver, measuring at the first SerDes a second eye height of a second eye of a second data sequence transmitted by the first SerDes; determining which of the second eye heights measured at the first SerDes comprises a second maximum eye height; and communicating to the second SerDes from the first SerDes the second driver impedance code value corresponding to the one of the second eye heights comprising the second maximum eye height for the second TX driver.

4. The method of claim 3, further comprising identifying at the first SerDes a second horizontal sampling position of the second eye, wherein for each of the plurality of second driver impedance code values, the measuring at the second SerDes the second eye height is performed at the second horizontal sampling position.

5. The method of any one of claims 1-4, wherein the data sequence comprises a pseudorandom data sequence (PRDS).

6. The method of any one of claims 1-5, further comprising, receiving at the second SerDes a data pattern transmitted from the first SerDes wherein the transmission corresponds to the impedance code value applied to the first TX driver.

7. The method of claim 6, wherein the data pattern comprises a series of binary ones.

8. The method of any one of claims 1-7, wherein the driver impedance code value is communicated to the first SerDes via sideband.

9. The method of claim 3 or 4, wherein the second driver impedance code value is communicated to the second SerDes via sideband.

10. The method of any one of claims 1-9, wherein the first SerDes and the second SerDes each comprise a plurality of lanes and wherein each of the measuring, determining, and communicating is performed for each of the lanes individually.

11. A calibration system comprising: a first serializer/deserializer (SerDes) comprising a first transmit driver; a second SerDes comprising a second transmit driver and connected to the first SerDes via a data transmission line; wherein the first SerDes further comprises circuitry for controlling an impedance of the first transmit driver in accordance with an impedance code received form the second SerDes; and wherein the second SerDes further comprises: circuitry for, for each of a plurality of impedance code values: transmitting the impedance code value to the first SerDes, the first SerDes for using the impedance code value for controlling the impedance of the first transmit driver; measuring an eye height of an eye of a predetermined data sequence transmitted by the second SerDes; circuitry for determining which one of the measured eye heights comprises a maximum eye height for the first transmit driver; and circuitry for communicating to the first SerDes the impedance code value associated with the one of the eye heights comprising the maximum eye height for the first TX driver.

12. The calibration system of claim 11, wherein the second SerDes further comprises circuitry for identifying a horizontal sampling position of the eye.

13. The calibration system of claim 12, wherein for each of the plurality of impedance code values, the measuring the eye height of the eye is performed at the horizontal sampling position.

14. The calibration system of any one of claims 11-13, wherein the second SerDes further comprises circuitry for transmitting to the predetermined data sequence.

15. The calibration system of claim 14, wherein the predetermined data sequence comprises a pseudorandom data sequence (PRDS).

16. The calibration system of any one of claims 11-15, wherein the first SerDes further comprises circuitry for transmitting a data pattern comprising a series of binary ones.

17. The calibration system of any one of claims 11-16, wherein the circuitry for transmitting the impedance code value to the first SerDes comprises a sideband communications channel. <u> </u> <u></u>

18. A calibration system comprising: a first serializer/deserializer (SerDes) comprising a first transmit driver, wherein an impedance of the first transmit driver is controlled by an impedance code; a second SerDes comprising a second transmit driver and connected to the first SerDes via a data transmission line, the second SerDes further comprising circuitry for measuring an eye of the second transmit driver, the circuitry comprising: a sampler for sampling data at an output of the second transmit driver; an error counter for comparing data output from the sampler with local data and outputting an error signal indicative of whether the data output from the sampler is the identical to the local data; a delay tuning block for tuning a delay clock of the sampler.

19. The calibration system of claim 18, further comprising a digital-to-analog converter (DAC) for providing the impedance code to the first transmit driver.

20. The calibration system of claim 18 or 19, further comprising a sideband communications channel, wherein a value for the impedance code is provided to the first SerDes from the second SerDes via the sideband communications channel.

### Variations and Other Notes

The detailed description, such as the “Select examples” section, provide various examples of the embodiments disclosed herein.

As used herein, the term “coupled to” or “coupled with” refers to a relationship between electronic components or circuit elements wherein the components are in electronic communication with one another and capable of transmitting and/or receiving electrical signals between them. The term “coupled to” does not require a direct physical or electrical connection between the coupled components. Rather, “coupled to” can encompass arrangements where the components are connected through one or more intervening elements, components, circuits, or transmission paths. For example, a first component may be “coupled to” a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/−20% of a target value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods, and devices of this disclosure each have several innovative aspects, no single one of which is solely responsible for all desirable attributes disclosed herein. Details of one or more implementations of the subject matter described in this specification are set forth in the description and the accompanying drawings.

What is claimed is:

1. A method for calibrating an impedance of a first transmit (TX) driver of a first bidirectional serializer/deserializer (SerDes), wherein the first bidirectional SerDes is connected to a second bidirectional SerDes by a data transmission line, the second bidirectional SerDes comprising a second TX driver, the method comprising:
for each of a plurality of driver impedance code values applied to the first TX driver measuring at the second SerDes an eye height of an eye of a data sequence transmitted by the second SerDes;
determining which of the measured eye heights comprises a maximum eye height; and
communicating to the first SerDes from the second SerDes the driver impedance code value corresponding to the one of the eye heights comprising the maximum eye height for the first TX driver.

2. The method of claim 1, further comprising identifying at the second SerDes a horizontal sampling position of the eye, wherein for each of the plurality of driver impedance code values, the measuring at the second SerDes the eye height is performed at the horizontal sampling position.

3. The method of claim 1, further comprising:
for each of a plurality of second driver impedance code values applied to the second TX driver, measuring at the first SerDes a second eye height of a second eye of a second data sequence transmitted by the first SerDes;
determining which of the second eye heights measured at the first SerDes comprises a second maximum eye height; and
communicating to the second SerDes from the first SerDes the second driver impedance code value corresponding to the one of the second eye heights comprising the second maximum eye height for the second TX driver.

4. The method of claim 3, further comprising identifying at the first SerDes a second horizontal sampling position of the second eye, wherein for each of the plurality of second driver impedance code values, the measuring at the second SerDes the second eye height is performed at the second horizontal sampling position.

5. The method of claim 1, wherein the data sequence comprises a pseudorandom data sequence (PRDS).

6. The method of claim 1, further comprising, receiving at the second SerDes a data pattern transmitted from the first SerDes wherein the transmission corresponds to the impedance code value applied to the first TX driver.

7. The method of claim 6, wherein the data pattern comprises a series of binary ones.

8. The method of claim 1, wherein the driver impedance code value is communicated to the first SerDes via sideband.

9. The method of claim 3, wherein the second driver impedance code value is communicated to the second SerDes via sideband.

10. The method of claim 1, wherein the first SerDes and the second SerDes each comprise a plurality of lanes and wherein each of the measuring, determining, and communicating is performed for each of the lanes individually.

11. A calibration system comprising:
a first serializer/deserializer (SerDes) comprising a first transmit driver;
a second SerDes comprising a second transmit driver and connected to the first SerDes via a data transmission line;
wherein the first SerDes further comprises circuitry for controlling an impedance of the first transmit driver in accordance with an impedance code received form the second SerDes; and
wherein the second SerDes further comprises:
circuitry for, for each of a plurality of impedance code values:
transmitting the impedance code value to the first SerDes, the first SerDes for using the impedance code value for controlling the impedance of the first transmit driver;
measuring an eye height of an eye of a predetermined data sequence transmitted by the second SerDes;
circuitry for determining which one of the measured eye heights comprises a maximum eye height for the first transmit driver; and
circuitry for communicating to the first SerDes the impedance code value associated with the one of the eye heights comprising the maximum eye height for the first TX driver.

12. The calibration system of claim 11, wherein the second SerDes further comprises circuitry for identifying a horizontal sampling position of the eye.

13. The calibration system of claim 12, wherein for each of the plurality of impedance code values, the measuring the eye height of the eye is performed at the horizontal sampling position.

14. The calibration system of claim 11, wherein the second SerDes further comprises circuitry for transmitting to the predetermined data sequence.

15. The calibration system of claim 14, wherein the predetermined data sequence comprises a pseudorandom data sequence (PRDS).

16. The calibration system of claim 11, wherein the first SerDes further comprises circuitry for transmitting a data pattern comprising a series of binary ones.

17. The calibration system of claim 11, wherein the circuitry for transmitting the impedance code value to the first SerDes comprises a sideband communications channel.

18. A calibration system comprising:
a first serializer/deserializer (SerDes) comprising a first transmit driver, wherein an impedance of the first transmit driver is controlled by an impedance code;
a second SerDes comprising a second transmit driver and connected to the first SerDes via a data transmission line, the second SerDes further comprising circuitry for measuring an eye of the second transmit driver, the circuitry comprising:
a sampler for sampling data at an output of the second transmit driver;
an error counter for comparing data output from the sampler with local data and outputting an error signal indicative of whether the data output from the sampler is the identical to the local data;
a delay tuning block for tuning a delay clock of the sampler.

19. The calibration system of claim 18, further comprising a digital-to-analog converter (DAC) for providing the impedance code to the first transmit driver.

20. The calibration system of claim 18, further comprising a sideband communications channel, wherein a value for the impedance code is provided to the first SerDes from the second SerDes via the sideband communications channel.
